(19) United States
(12) Patent Application Publication
(10) Pub. No.: US 2012/0152308 A1
(43) Pub. Date: Jun. 21, 2012

(54) STRUCTURALLY BREAKING UP A TWO-AXIS TRACKER ASSEMBLY IN A CONCENTRATED PHOTOVOLTAIC SYSTEM

(75) Inventors: Wayne Miller, Los Altos, CA (US); Brian Hinman, Los Gatos, CA (US); Victor Ocegueda, Fremont, CA (US); Anthony Wlodarczyk, Fremont, CA (US)

(73) Assignee: GREENVOLTS, INC, FREMONT, CA (US)

(21) Appl. No.: 13/227,645

(22) Filed: Sep. 8, 2011

Related U.S. Application Data
(60) Provisional application No. 61/424,537, filed on Dec. 17, 2010.
(60) Provisional application No. 61/424,515, filed on Dec. 17, 2010.
(60) Provisional application No. 61/424,518, filed on Dec. 17, 2010.

(51) Int. Cl. H01L 31/052

(52) U.S. Cl. 136/246

(57) ABSTRACT

Methods and apparatus are described for a two axis tracking mechanism for a concentrated photovoltaic system. A solar array of the two axis tracking mechanism is structurally broken up to have multiple independently movable sets of concentrated photovoltaic solar (CPV) cells. Further, the remainder of the two-axis tracker is manufactured in simple sections that assemble easily in the field while maintaining the alignment of the tracker assembly. The CPV cells are located in two or more paddle assemblies, and the paddle assemblies couple to a common roll axle. Each of the multiple paddle assemblies contains its own set of the CPV solar cells that is independently movable on its own tilt axle from other sets of CPV cells on that two axis tracking mechanism. Each paddle assembly has its own drive mechanism for that tilt axle.

### RELATED APPLICATIONS

This application is a continuation in part of and claims the benefit of and priority to U.S. Provisional Application titled “Integrated electronics system” filed on Dec. 17, 2010 having application Ser. No. 61/424,537, U.S. Provisional Application titled “Two axis tracker and tracker calibration” filed on Dec. 17, 2010 having application Ser. No. 61/424,515, and U.S. Provisional Application titled “Photovoltaic cells and paddles” filed on Dec. 17, 2010 having application Ser. No. 61/424,518.

### NOTICE OF COPYRIGHT

A portion of the disclosure of this patent document contains material that is subject to copyright protection. The copyright owner has no objection to the facsimile reproduction by anyone of the interconnect as it appears in the Patent and Trademark Office Patent file or records, but otherwise reserves all copyright rights whatsoever.

### FIELD

In general, a photovoltaic system having a two-axis tracker assembly for a photovoltaic system is discussed.

### BACKGROUND

A two-axis tracker may break up its solar array for more efficient operation. A two axis tracker may be designed for easier of installation in the field.

### SUMMARY

Various methods and apparatus are described for a photovoltaic system. In an embodiment, a common roll axle is located between 1) stanchions, and 2) multiple CPV paddle assemblies. Each of the multiple paddle assemblies contains its own set of the CPV solar cells contained within that CPV paddle assembly that is independently movable from other sets of CPV cells on that two axis tracking mechanism. Each paddle assembly is independently moveable on its own tilt axis.

### BRIEF DESCRIPTION OF THE DRAWINGS

The multiple drawings refer to the embodiments of the invention.

FIGS. 1A and 1B illustrate diagrams of an embodiment of a two axis tracking mechanism for a concentrated photovoltaic system having multiple independently movable sets of concentrated photovoltaic solar (CPV) cells.

FIG. 2 illustrates a diagram of an embodiment of a roll bearing assembly with pinholes to maintain alignment.

FIG. 3 illustrates a side perspective diagram and an exploded view of an embodiment of roll bearing assembly with plastic bearings inside.

FIG. 4 illustrates a side perspective diagram of an embodiment of a linear actuator coupling to a folding structure of each paddle assembly.

FIG. 5 illustrates a diagram of an embodiment of a center truss coupling a paddle pair to form a paddle assembly controllable by a single linear actuator.

FIG. 6 illustrates a diagram of an embodiment of a section of the conical roll axle and a perpendicular tilt axle, where two or more sections couple when installed in the field to form a common role axle of the tracker assembly.

FIG. 7 illustrates an exploded diagram of an embodiment of a paddle with its skeletal frame and the CPV modules, each with multiple CPV cells inside, where the CPV modules are installed and housed in the skeletal frame.

FIG. 8 illustrates a diagram of an embodiment of a paddle with its CPV cells installed and the central support tube of the paddle aligning to easily slide onto the tilt axle when being installed in the field.

While the invention is subject to various modifications and alternative forms, specific embodiments thereof have been shown by way of example in the drawings and will herein be described in detail. The invention should be understood to not be limited to the particular forms disclosed, but on the contrary, the intention is to cover all modifications, equivalents, and alternatives falling within the spirit and scope of the invention.

### DETAILED DISCUSSION

In the following description, numerous specific details are set forth, such as examples of specific cells, named components, connections, types of connections, etc., in order to provide a thorough understanding of the present invention. It will be apparent, however, to one skilled in the art that the present invention may be practiced without these specific details. In other instances, well known components or methods have not been described in detail but rather in a block diagram in order to avoid unnecessarily obscuring the present invention. Further specific numeric references such as a first paddle, may be made. However, the specific numeric reference should not be interpreted as a literal sequential order but rather interpreted that the first paddle is different than a second paddle. Thus, the specific details set forth are merely exemplary. The specific details may be varied from and still be contemplated to be within the spirit and scope of the present invention.

In general, various methods and apparatus are discussed for a photovoltaic system. In an embodiment, a solar array of the two axis tracking mechanism is structurally broken up to have multiple independently movable sets of concentrated photovoltaic solar (CPV) cells. Further, the remainder of the two-axis tracker assembly is manufactured in simple sections that assemble easily in the field while maintaining the alignment of the tracker assembly. The CPV cells are located in two or more paddle assemblies and the paddle assemblies couple to a common roll axle. Each of the multiple paddle assemblies contains its own set of the CPV solar cells that is independently movable on its own tilt axle from other sets of CPV cells on that two axis tracking mechanism. Each paddle assembly has its own drive mechanism for that tilt axle. Structurally breaking up the solar array allows for more efficient operation of the array and provides for an easier installation of the aggregate two-axis tracker assembly in the field.

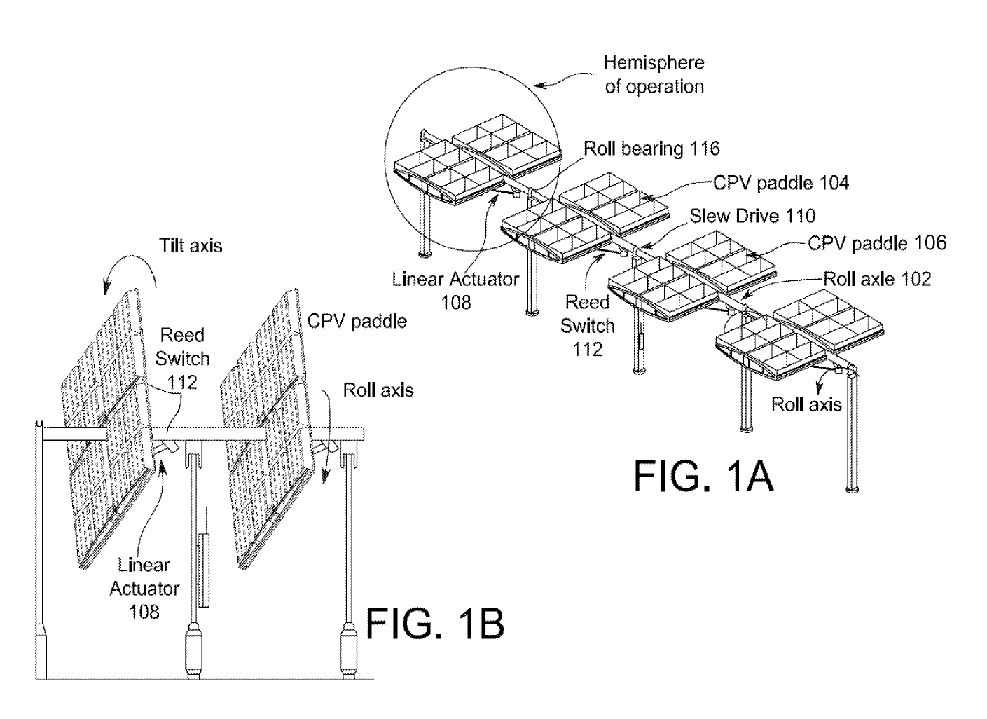

FIGS. 1A and 1B illustrate diagrams of an embodiment of a two axis tracking mechanism for a concentrated photovoltaic system having multiple independently movable sets of concentrated photovoltaic solar (CPV) cells. FIG. 1A shows the paddle assemblies containing the CPV cells, such as four paddle assemblies, at a horizontal position with respect to the common roll axle. FIG. 1B shows the paddle assemblies containing the CPV cells tilted up vertically by the linear actuators with respect to the common roll axle.

A common roll axle 102 is located between 1) stanchions, and 2) multiple CPV paddle assemblies. Each of the multiple paddle assemblies, such as a first paddle assembly 104, contains its own set of the CPV solar cells contained within that CPV paddle assembly that is independently movable from other sets of CPV cells, such as those in the second paddle assembly 106, on that two axis tracking mechanism. Each paddle assembly is independently moveable on its own tilt axis and has its own drive mechanism for that tilt axle. The drive mechanism may be a linear actuator with a brushed DC motor. An example number of twenty-four CPV cells may exist per module, with eight modules per CPV paddle, two CPV paddles per paddle assembly, a paddle assembly per tilt axis, and four independently-controlled tilt axes per common roll axis.

Each paddle pair assembly has its own tilt axis linear actuator, such as a first linear actuator 108, for its drive mechanism to allow independent movement and optimization of that paddle pair with respect to other paddle pairs in the two-axis tracker mechanism. Each tilt-axle pivots perpendicular to the common roll axle 102. The common roll axle 102 includes two or more sections of roll beams that couple to the slew drive motor 110 and then the roll beams couple with a roll bearing assembly having pin holes for maintaining the roll axis alignment of the solar two-axis tracker mechanism at the other ends, to form a common roll axle 102. The slew drive motor 110 and roll bearing assemblies are supported directly on the stanchions. A motor control board in the integrated electronics housing on the solar tracker causes the linear tilt actuators and slew drive motor 110 to combine to move each paddle assembly and its CPV cells within to any angle in that paddle assembly's hemisphere of operation. Each paddle assembly rotates on its own tilt axis and the paddle assemblies all rotate together in the roll axis on the common roll axle 102.

The tracker circuitry uses primarily the Sun's angle in the sky relative to that solar array to move the angle of the paddles to the proper position to achieve maximum irradiance. A hybrid algorithm determines the known location of the Sun relative to that solar array via parameters including time of the day, geographical location, and time of the year supplied from a local GPS unit on the tracker, or other similar source. The two-axis tracker tracks the Sun based on the continuous latitude and longitude feed from the GPS and a continuous time and date feed. The hybrid algorithm will also make fine tune adjustments of the positioning of the modules in the paddles by periodically analyzing the power (I-V) curves coming out of the electrical power output circuits to maximize the power coming out that solar tracker.

The hybrid solar tracking algorithm supplies guidance to the motor control board for the slew drive and tilt actuators to control the movement of the two-axis solar tracker mechanism. The hybrid solar tracking algorithm uses both 1) an Ephemeris calculation and 2) an offset value from a matrix to determine the angular coordinates for the CPV cells contained in the two-axis solar tracker mechanism to be moved to in order to achieve a highest power out of the CPV cells. The motion control circuit is configured to move the CPV cells to the determined angular coordinates resulting from the offset value being applied to the results of the Ephemeris calculation.

Note, optimally tracking the Sun with four independently moveable paddle pair assemblies on a solar array is easier and more accurate across the four paddle pairs than with a single large array occupying approximately the same amount of area as the four arrays. In an example, four or more paddles, each contains a set of CPV cells, and form a part of the two-axis solar tracker mechanism. Each of these paddles may be part of a paddle pair assembly that rotates on its own tilt axis. For example, both a first paddle containing CPV cells on a first section of a first tilt axle and a second paddle containing CPV cells on a second section of the first tilt axle rotate on the axis of that first tilt axle. Likewise, both a third paddle containing CPV cells on a first section of a second tilt axle and a fourth paddle containing CPV cells on a second section of the second tilt axle rotate on the axis of that second tilt axle. In addition, both the first and second tilt axles connect perpendicular to the common roll axle that universally rotates all of the tilt axles.

The two-axis tracker includes a precision linear actuator for each of the paddle pairs in the four paddle pairs joined on the shared stanchions as well as the slew drive connect to the common roll axle 102. A set of magnetic reed sensors can be used to determine reference position for tilt linear actuators to control the tilt axis as well as the slew motor to control the roll axis on the common roll axle 102. Each tilt linear actuator may have its own magnetic reed switch sensor, such as a first magnetic reed sensor 112. For the tilt reference reed sensor, on for example the south side of each paddle pair and on the east side of the roll beam, a tilt sensor mount and tilt sensor switch is installed in the holes provided on the roll beam past the end of the paddle. Also, on the paddle assembly, the magnet mount and magnet are screwed in.

An integrated electronics system housing installed on the tracker may include motion control circuits, inverters, ground fault circuits, etc. and act as a local system control point for that solar array.

The paddle structure has only a few components that need to be assembled to install and secure in place in the field on the tracker assembly. The four tilt axle and roll beam assemblies are supported by five stanchions, and have the one integrated electronics system to control that tracker assembly. The stanchions support the tracker assembly and are shared between CPV paddle pairs. At the shared and non-shared stanchions, the ends of the conical roll beams of each roll beam couple, for support, into the roll bearings. The two-axis tracker includes the conical shaped sections of roll beam (fixed axle) with multiple paddle-pair tilt-axle pivots perpendicular to the roll beam. Accordingly, each paddle pair has its own section of roll beam and own tilt axle. Each paddle pair has its own tilt axis linear actuator to allow independent movement and optimization of that paddle pair with respect to other paddle pairs in the tracker assembly. The tilt actuators and the slew drive motor control the position of the tilt and roll angles of the paddles to orient the CPV cells such that the maximum incoming light is focused to the photovoltaic collectors/receivers in the paddle pair.

The slew drive motor is located and couples to the common roll axle in middle of the common roll axle of the two axis tracker mechanism, which gives a better overall pointing accuracy to the paddle assemblies at the ends of the common roll axle because of being closer and more proximate to the slew drive motor than if the slew drive motor was coupled somewhere off-center of the common roll axle. Note, a limited amount, such as four, paddle pair assemblies per tracker creates acceptable twisting torque on the common roll axle to not cause pointing errors or material fatigue on the common roll axle.

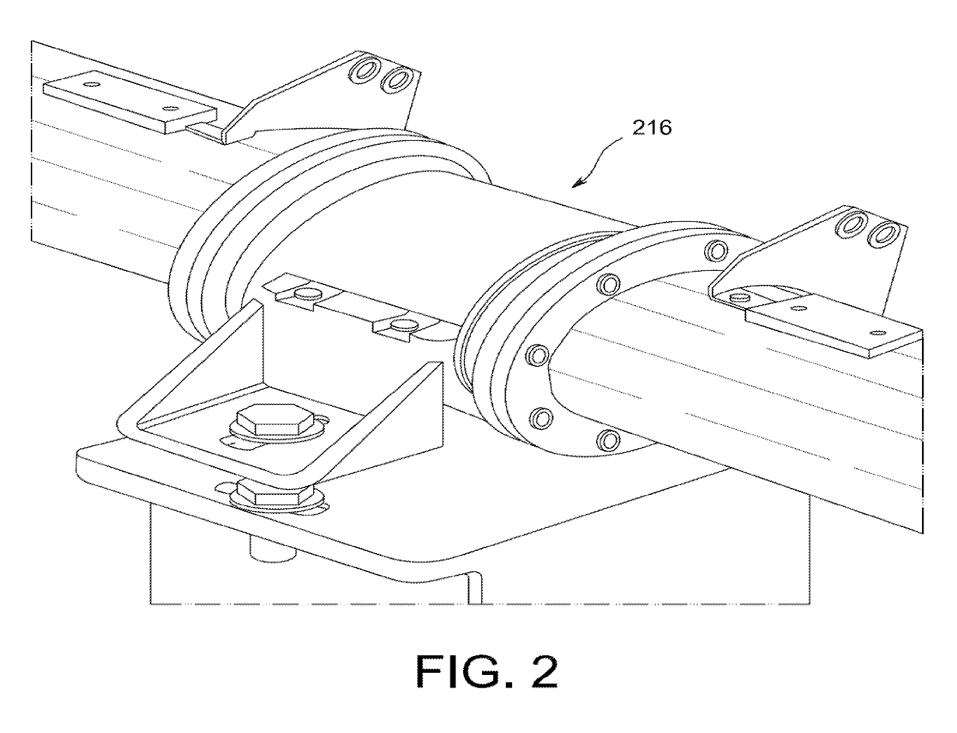

FIG. 2 illustrates a diagram of an embodiment of a roll bearing assembly with pinholes. Each roll bearing 216 couples between the narrower ends of the conical roll axle from the two-axis tracker. The roll bearing assembly 216 with pinholes maintains the roll axis alignment of the solar tracking mechanism between neighboring independently moveable CPV paddle pairs. Each roll bearing couples and pins between a pair of stanchions. Each roll bearing assembly 216 may have flanged connection points for assisting in alignment and ease of installation in the field. The two-axis tracker has a slew drive and two or more roll bearings, which couple and pin with the sections of the roll axle to form the common roll axle. The roll bearings align and support the rotation of the common roll axle sections of each tracker.

A spindle of the roll axle may connect into a bottom half of the roll bearing 216. While in this position, the roll beam and the flanges are aligned using the indexing pins on the plate, and mated together.

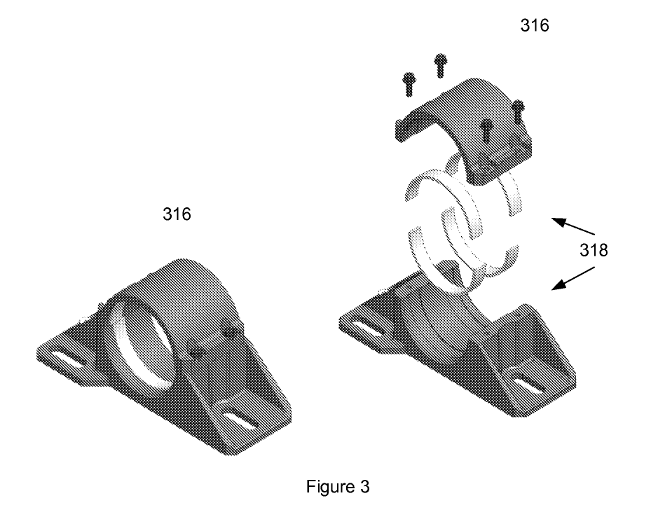

FIG. 3 illustrates a side perspective diagram and an exploded view of an embodiment of roll bearing assembly with plastic bearings inside. Each roll bearing assembly 316 may have ultra high molecular weight plastic bearings 318 designed for life-long wear to minimize maintenance in the field. The rotational constraint on the common roll axle is provided by the top cap. Axial constraint is provided by the machined slot.

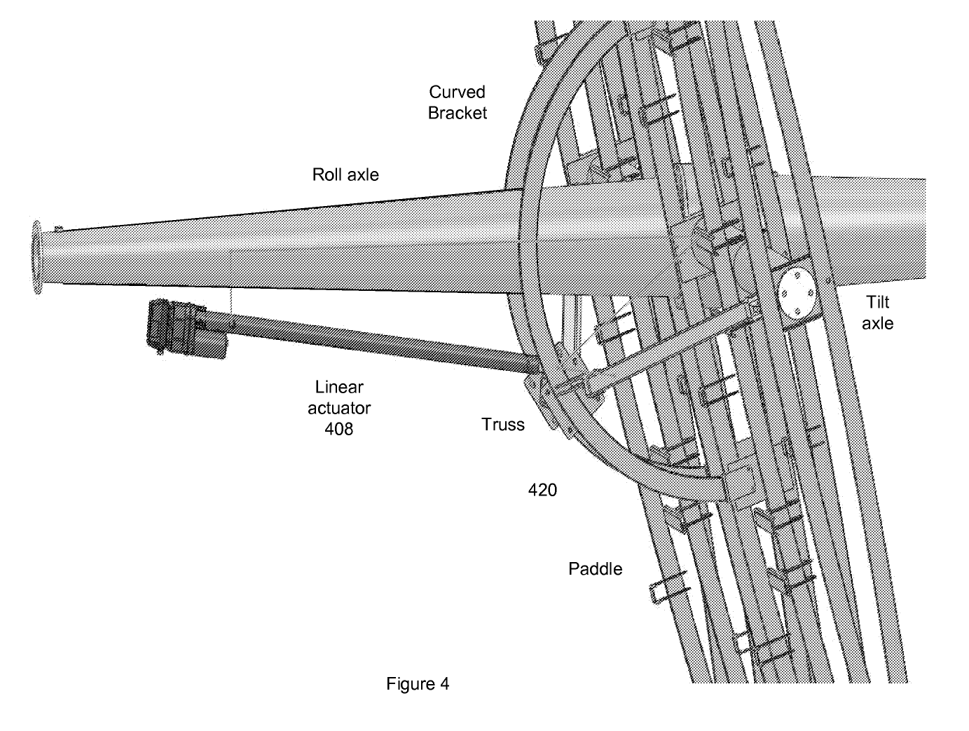

FIG. 4 illustrates a side perspective diagram of an embodiment of a linear actuator coupling to a folding structure of each paddle assembly. The linear actuator 408 also connects and run along the length of the conical roll axle. Note, the skeletal form of both paddles in the paddle pair is shown without the set of CPV modules installed to illustrate a more clear connectivity of this example embodiment of the roll axle, tilt axle, folding structure, and linear actuator.

As discussed, a linear actuator 408 per each paddle pair allows independent tilt rotation for each of these paddle pairs on the solar array and control of the paddle's tilt actuation. Note, other drive mechanism may also be used to move the paddle pair.

The folding structure 420 couples to and is part of the paddle assembly. The folding structure 420 has multiple curved brackets. Each curved bracket has hinges to fold flat against its paddle skeletal frame when the paddle is shipped. A center truss connects between the curved brackets when installed in the field to allow the connected linear actuator to cause paddle tilt articulation on the tilt axle. The linear actuator 408 couples to the bottom of the roll axle on one end and to the center truss 408 of the folding structure on the other end. The center truss couples to the inside surface of the two semicircular curved spider brackets. A turnbuckle arm on each paddle couples to the outside surface of its semicircular curved spider bracket.

The linear actuator 408 couples to the turnbuckle and center truss of the paddle structure in a nearly vertical orientation. The linear actuator motor connects into its mounting bracket on the roll axle, and the eyebolt on the end of the extender arm of the linear actuator uses a clevis pin and a cotter pin into its receiving bracket on the center truss. The turnbuckle arm with its two clevis pins and cotter pins that couple to the curved brackets on hinges are part of the folding structure 420. With the curve bar on its hinges in its fully extended position, the turnbuckle arm can be installed in either of two known and fixed positions on the curved spider bracket. The clevis pins and cotter pins make the connections between the turnbuckle eyebolts and the brackets receiving them. The turnbuckle arm may be extended or contracted by turning the turnbuckle arm to match the holes in the curve bar extension. This installation of the turnbuckle arm is repeated for the other paddle in the pair. During the horizontal leveling of the paddle pair, small adjustments occur to level the paddles by turning either side's turnbuckle arm.

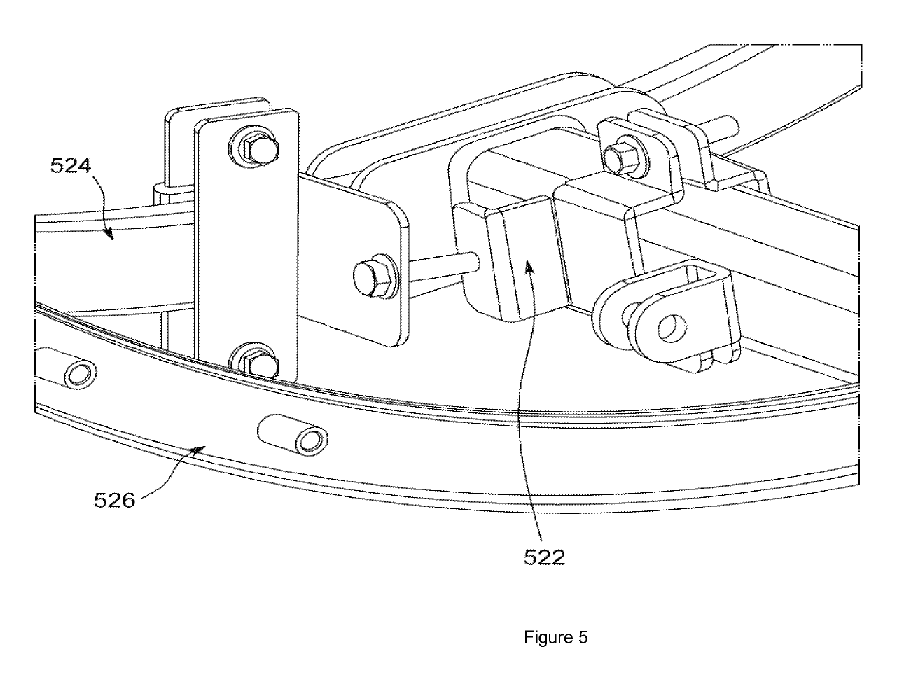

FIG. 5 illustrates a diagram of an embodiment of a center truss coupling a paddle pair to form a paddle assembly controllable by a single linear actuator. The center truss 522 is installed and connected between the semicircular curved spider brackets 524, 526 on each paddle in order to make the two paddles a single paddle assembly controllable by a single linear actuator. When the truss 522 is installed, the paddle pair is now coupled together. The adjustment of the nuts on this center truss 524, 526 may level the paddle pair in the vertical axis (i.e. make the paddles co-planar). Many other adjustment mechanisms can be designed into the coupling of the truss 522 to curved brackets 524, 526 but the adjustment mechanism is designed into this coupling of the two. This folding structure consists of the center truss 522, two curved brackets 524, 526 on their hinges connected to the paddle frame, and the two turnbuckle arms connected to the paddle frame on each paddle, and couples to its own linear actuator, which is used controlling paddle tilt articulation. In an embodiment, after the folding structure's center truss 522 is installed, then the paddle pair may be aligned and then finally the linear actuator can be coupled to the center truss 522 of the folding structure.

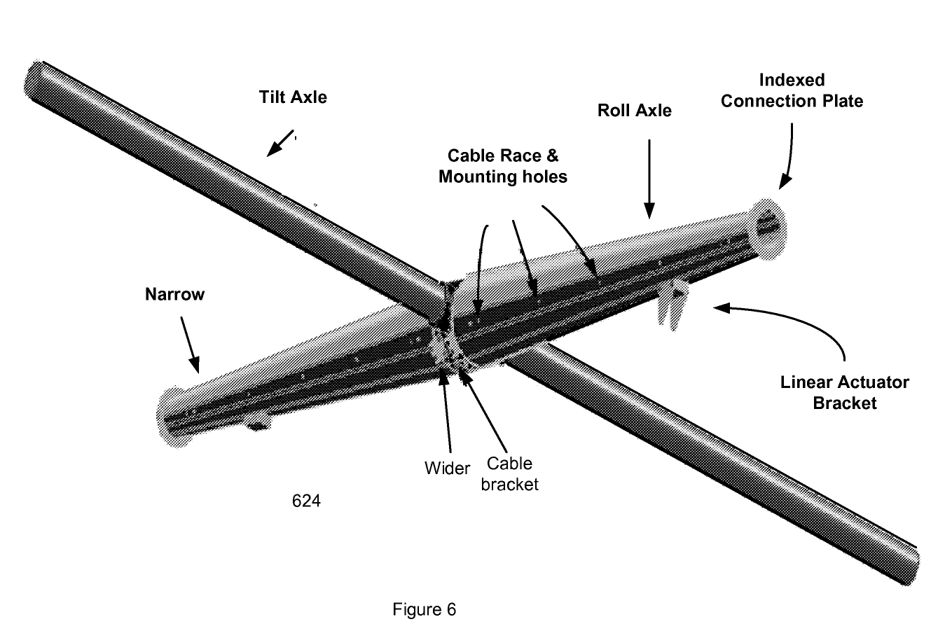

FIG. 6 illustrates a diagram of an embodiment of a section of the conical roll axle and a perpendicular tilt axle. The common roll axle includes two or more conical shaped sections of roll beams/axles 624 that couple together via any of 1) a coupling mechanism, 2) a roll bearing assembly, 3) a slew drive motor coupling to a flanged narrower section of the conical shaped roll axle, and 4) any combination of the three. The narrower ends of the roll beam each may have a flanged indexed connection plate to assist in ease of installation in the field and the maintaining the alignment of the common roll axle throughout the entire tracker assembly. A wider section of the conical shaped roll beam is connected approximate the tilt-axle to assist in the higher torque requirements that occur at that intersection. The multiple paddle-pairs each have a tilt-axle that pivots perpendicular to the common roll axle.

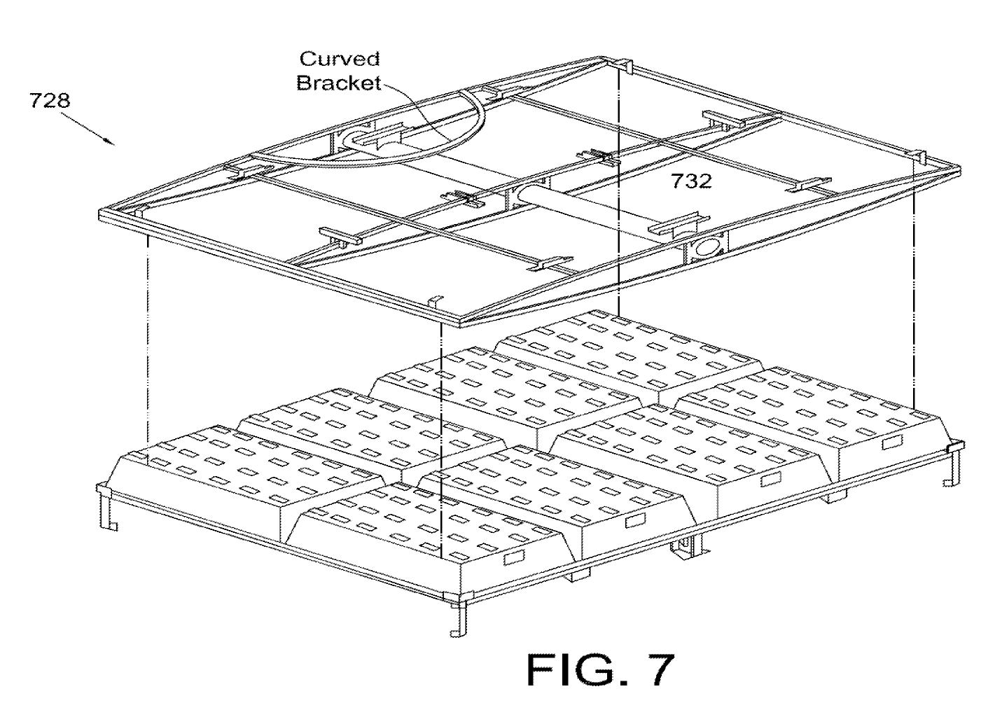

FIG. 7 illustrates an exploded diagram of an embodiment of a paddle with its skeletal frame and the CPV modules, each with multiple CPV cells inside, where the CPV modules are installed and housed in the skeletal frame. The two-axis tracker mechanism for the concentrated photovoltaic has multiple paddle structures that contain the CPV solar cells. A paddle 728 is constructed such that its set of CPV cells contained in the paddle maintain their alignment in three dimensions when installed in the paddle. Each paddle structure 728 has a skeleton frame that contains multiple individual CPV cells arranged in a grid like pattern that are pre-aligned in the three dimensions with each other during the fabrication process when the concentrated photovoltaic cells are installed in the paddle. Many CPV solar cells may be contained in each rectangular housing module, such as a first CPV module. Each paddle assembly also has a centerline-aligned tube 732 connected to the skeleton framing. This overall structure of the paddle maintains the three dimensional alignment of the installed CPV cells during shipment as well as during an operation of the two axis tracker mechanism. An example two-axis tracker unit may have twenty-four CPV solar cells per module, eight modules per paddle, two or more paddles per paddle assembly, and a paddle assembly per tilt axis.

In an embodiment, each CPV module assembly may be created with a rectangular grid containing, for example, twenty-four individual concentrated photovoltaic cells, each CPV cell in its own solar receiver. The CPV power units with the solar cells may optically couple with Fresnel Lenses aligned during the manufacturing process. The modules that have been fabricated to have the CPV receivers installed aligned vertically, horizontally, with respect to the other receivers installed in the module template. Thus, the CPV cells in an individual module are aligned in three dimensions with each other by the fabrication process, and use keyed parts shaped or pinned to fit together in only one way so that all of the solar receivers containing the CPV cells maintain their alignment when installed in a CPV module. The paddle structure 728 then maintains the alignment of the installed modules during shipment and during the operation of the solar arrays.

The CPV power units collect and concentrate the sunlight. However, by having multiple paddles forming the solar array of the two-axis tracker, the surface area of densely populated CPV cells is broken up into pairs of paddles compared to a single larger unitary array, which allows for easier shipping and easier installation.

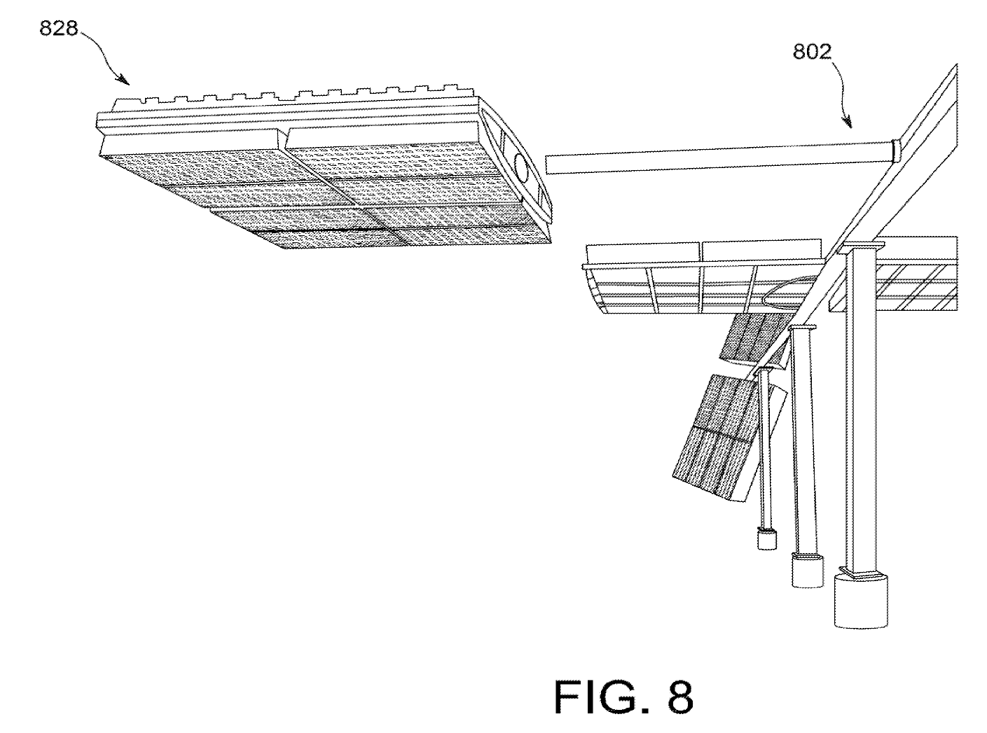

FIG. 8 illustrates a diagram of an embodiment of a paddle with its CPV cells installed and the central support tube of the paddle aligning to easily slide onto the tilt axle when being installed in the field. Assembly of the parts in the field of the two-axis tracker assembly is made easy by many design features including sliding the paddle structure 828 onto a section of tilt axle, and coupling the sections of the common roll axle 802 together at manufactured-in aligned connection points of the slew drive motor and roll bearings.

As discussed, each paddle structure 828 has a centerline-aligned tube that slides onto its tilt axle. Two or more tilt axles couple to the common roll axle 802 and each side of the tilt axle has a paddle structure 828 slid and secured onto that tilt axle. The tilt axle couples to the wider conical portion of a section of roll axle 802. Two or more sections of roll beams couple to the slew drive motor on one end of the beam and then each roll beam couples with a corresponding roll bearing at the other end. Where the narrower ends of the conical roll axle each may have a flanged indexed connection plate and each roll bearing assembly has alignment pinholes for maintaining the roll axis alignment of the solar two-axis tracker mechanism. The slew drive motor and the roll bearing assemblies are supported directly on the stanchions. These components of the two-axis tracker mechanism are easily assembled in the field.

Thus, the solar array support structure may have couplings for easy installation of the paddle 828; and correspondingly, the paddle's design itself is configured for easy installation sliding of the paddle 828 onto the tilt axle of the support structure mounted in concrete post. The manufactured and assembled paddle 828 with its CPV modules assemblies already installed and aligned when arriving on the solar generation site assists in making the installation easier and faster. Also, the tracker assembly itself consisting of small number of unique components, such as eight main distinct types of components, results in a fewer number of steps/operations to install the arrays and paddle. The lead-in features on the central tube help to align parts and prevent damage. Note, the cylindrical center support tube of the paddle is made of a thin walled diameter material compared to the cylindrical tilt axis arm. Most of the torque of moving the paddle during operation will occur on the tilt axle rather than on the central support tube, which is designed for coupling to the tilt axle.

An example process for assembling and installing the paddles with their already installed and aligned CPV cells may be as follows. Overall, the steps can be simply to lift a paddle out of the shipping packaging, turn the paddle horizontal, slide the paddle onto the tilt axle, secure the install of the paddle to the tilt axle occur with a compression ring, and verify the alignment of the paddles. An entire tracker physical alignment process may occur with a laser so that the paddles maintain their alignment.

### Additional Points on the Reed Switches and Other Components

The reed switch contact portion is installed at a known fixed location on the stationary casing of the slew drive. The magnetic portion of the reed switch is installed at a known fixed location on the rotating portion that couples to the common roll axle. Thus, a set of, for example, five magnetic reed switches are used to provide reference positions of the paddles during operation. This set of magnetic reed sensors, one at each measured axis, is used to determine 1) a reference position for the tilt linear actuators to control the tilt axis of the CPV cells as well as 2) a reference position for the slew drive motor 210 to control the roll axis of the CPV cells. A total of, for example, four magnetic reed switches are used on the bottoms of the four paddle pairs indicate a tilt axis angle of 0, 0 for the linear actuators, and one magnetic reed switch is used on the slew drive motor to indicate a roll axis angle of 0, 0 for the slew drive. These magnetic reed sensors are located and configured to allow a degree of rotation on the roll axis of the solar tracker to be accurately correlatable to a number of rotations of the slew drive motor. Similarly, the magnetic reed sensors for the tilt axis are located and configured to allow a position along each linear actuator to be accurately correlatable to a degree of rotation on the tilt axis of the solar tracker.

Note, when each paddle pair is aligned as described above, the roll angle of each pair and tilt angle of each pair should have been written down and put into a memory. Ideally, all measurements will be the same—close to but not necessarily zero degrees. A virtual offset is created between the known and verified physically horizontally level paddle pairs and where the reed switches indicate that the slew drive motor is at coordinates 0, 0 as well as when the known and verified physically vertically level paddle pair are at level and the linear actuator is at coordinates 0, 90. The turnbuckle arms can be used as fine adjustments in the tilt axis and the nuts and bolts on the center truss can be used as fine adjustments in the roll axis until the readings are the essentially the same, indicating that the CPV Modules are in the same plane (or parallel planes). Note, after alignment, under the paddle, lock nuts located on both sides of the turnbuckle arm should be locked down to prevent further turning. Re-verify and store in memory the angle reading noted on the digital levels (variation from zero degrees) for this pair.

The motor control circuits in the integrated electronics housing may include controls for and parameters on the slew drive, tilt linear actuators, and the above reference reed switches. Also, the integrated electronics housing may contain the inverter AC generation circuits. The housing may also contain the local code employed for the Sun tacking algorithms for each paddle assembly.

Although the foregoing embodiments have been described in some detail for purposes of clarity of understanding, the invention is not limited to the details provided. The Solar array may be organized into one or more paddle pairs. Functionality of circuit blocks may be implemented in hardware logic, active components including capacitors and inductors, resistors, and other similar electrical components. Flange may be replaced with couplings and similar connectors. Functionality can be configured with hardware logic, software coding, and any combination of the two. Any software coded algorithms or functions will be stored on a corresponding machine-readable medium in an executable format. The two axis tracker assembly may be a multiple axis tracker assembly in three or more axes. There are many alternative ways of implementing the invention. The disclosed embodiments are illustrative and not restrictive.

We claim:

1. A two axis tracking mechanism for a concentrated photovoltaic system having multiple independently movable sets of concentrated photovoltaic solar (CPV) cells; comprising:
a common roll axle located between 1) stanchions and 2) multiple paddle assemblies, where each of the multiple paddle assemblies contains its own set of the CPV solar cells that is independently movable on its own tilt axle from other sets of CPV cells on that two axis tracking mechanism, where each paddle assembly has its own drive mechanism for that tilt axle.

2. The two-axis tracker mechanism for the concentrated photovoltaic system of claim 1, further comprising:
a roll bearing assembly with pinholes for maintaining a roll axis alignment of the solar tracking mechanism between neighboring independently moveable CPV paddle pairs, and where a roll bearing assembly couples and pins to the common roll axle between the stanchions.

3. The two axis tracker mechanism for the concentrated photovoltaic system of claim 1, where each paddle pair assembly has its own tilt axis linear actuator for its drive mechanism to allow independent movement and optimization of that paddle pair with respect to other paddle pairs in the two axis tracker mechanism, where each tilt-axle pivots perpendicular to the common roll axle.

4. The two-axis tracker mechanism for the concentrated photovoltaic system of claim 3, further comprising:
a first paddle assembly;
a folding structure couples to and is part of the first paddle assembly and connects to one end of a first linear actuator, where the folding structure has multiple curved brackets, where curved bracket has hinges to fold flat against its paddle skeletal frame when the paddle is shipped, and a center truss to connect between the curved brackets when installed in the field to allow the connected first linear actuator to cause paddle tilt articulation on the tilt axle, and
each paddle assembly rotates on its own tilt axis and the paddle assemblies all rotate together in the roll axis on the common roll axle.

5. The two axis tracker mechanism for the concentrated photovoltaic system of claim 1, where the common roll axle includes two or more conical shaped sections of roll beams that couple together via any of 1) a coupling mechanism, 2) a roll bearing assembly, 3) a slew drive motor coupling to a flanged narrower section of the conical shaped roll beam, and 4) any combination of the three, and where the multiple paddle-pairs each have a tilt-axle that pivots perpendicular to the common roll axle and a wider section of the conical shaped roll beam is connected approximate the tilt-axle.

6. The two-axis tracker mechanism for the concentrated photovoltaic system of claim 3, further comprising:
a slew drive motor;
two or more roll bearing assemblies;
two or more stanchions; and
where the common roll axle includes two or more sections of roll axles that couple to the slew drive motor and then the roll axles couple with roll bearing assembly with pin holes for maintaining the roll axis alignment of the solar two axis tracker mechanism at the other ends, to form a common roll axle, where the slew drive motor and roll bearing assemblies are supported directly on the stanchions, and
a motor control board in an integrated electronics housing located on the two axis tracker causes the linear tilt actuators and slew drive motor to combine to move each paddle assembly and its CPV cells within to any angle in that paddle assembly's hemisphere of operation.

7. The two axis tracker mechanism for the concentrated photovoltaic system of claim 1, where a paddle is constructed such that its set of CPV cells contained in the paddle maintain their alignment in three dimensions when installed in the paddle, where paddle assembly has a skeleton frame that contains multiple individual CPV cells arranged in a grid like pattern that are pre-aligned in the three dimensions with each other during the fabrication process when the concentrated photovoltaic cells are installed in the paddle, and each paddle also has a center-line aligned tube connected to the skeleton framing, and this overall structure of the paddle assembly maintains the three dimensional alignment of the installed CPV cells during shipment as well as during an operation of the two axis tracker mechanism.

8. The two-axis tracker mechanism for the concentrated photovoltaic system of claim 1, further comprising:
a slew drive motor;
two or more roll bearing assemblies with flange connection points and ultra high molecular weight plastic bearings;
two or more stanchions;
each paddle assembly also has a center-line aligned tube that slides onto its tilt axle, and two or more tilt axles couple to the common roll axle and each side of the tilt axle has a paddle assembly slid and secured onto that tilt axle; and
where the common roll axle includes
two or more sections of roll axles that couple to the slew drive motor on one end of the axle and then each roll axle couples with one of the roll bearing assemblies with pin holes for maintaining the roll axis alignment of the solar two axis tracker mechanism at the other end, to form a common roll axle, where the slew drive motor and the roll bearing assemblies are supported directly on the stanchions, and where these components of the two axis tracker mechanism are easily assembled in the field.

9. The two-axis tracker mechanism for the concentrated photovoltaic system of claim 1, further comprising:
where four or more paddles each contain a set of CPV cells and form a part of the two-axis solar tracker mechanism, and each paddle rotates on its own tilt axis,
a set of magnetic reed sensors, one at each measured axis, used to determine 1) a reference position for the tilt linear actuators to control the tilt axis of the CPV cells as well as 2) a reference position for the slew drive motor to control the roll axis of the CPV cells,
where one or more of the magnetic reed sensors are located and configured to allow a degree of rotation on the roll axis of the solar tracker to be accurately correlatable to a number of rotations of the slew drive motor,
where one or more of the magnetic reed sensors are located and configured to allow a position along each linear actuator to be accurately correlatable to a degree of rotation on the tilt axis of the solar tracker, and
where a first magnetic reed switch portion of a first magnetic reed sensor is located on an outer casing of the slew drive by the common roll axle coupled to the slew drive, and the magnetic portion of the magnetic reed sensor is affixed to a drive portion of the slew drive coupling to the common roll axle.

10. The two-axis tracker mechanism for the concentrated photovoltaic system of claim 1, further comprising:
a first paddle containing CPV cells on a first section of a first tilt axle and a second paddle containing CPV cells on a second section of the first tilt axle;
a third paddle containing CPV cells on a first section of a second tilt axle and a fourth paddle containing CPV cells on a second section of the second tilt axle, where both the first and second tilt axles connect perpendicular to the common roll axis; and
a first stanchion supports the two-axis tracker assembly and is located between the first tilt axle and the second tilt axle.

11. The two axis tracker mechanism for the concentrated photovoltaic system of claim 1, where two or more sections of a conical roll axle and perpendicular tilt axle are coupled together in the two axis tracker assembly, and the narrower ends of the conical roll axle each may have a flanged indexed connection plate to assist in ease of installation in the field and the maintaining the alignment of the common roll axle throughout the entire two axis tracker assembly, and where each paddle structure had a curved bracket, and a center truss connects between the curved brackets of at least two paddle structures when installed in the field to form a paddle assembly to allow a connected linear actuator to cause paddle tilt articulation for that paddle assembly on the tilt axle, and
where two or more sections of the conical roll axle couple to the slew drive motor on one end of the roll axle and then each roll axle couples with a corresponding roll bearing at the other end, and the common roll axle, the slew drive motor and roll bearings are supported directly on the stanchions and each tilt axle couples to the wider conical portion of its section's of roll axle.

12. The two axis tracker mechanism for the concentrated photovoltaic system of claim 1, where the slew drive motor is located and couples to the common roll axle in middle of the common roll axle of the two axis tracker mechanism, which gives a better overall pointing accuracy to the paddle assemblies at the ends of the common roll axle because of being closer and more proximate to the slew drive motor than if the slew drive motor was coupled somewhere off-center of the common roll axle.

13. A method for a two axis tracking mechanism for a concentrated photovoltaic system, comprising:
structurally breaking up a solar array of the two axis tracking mechanism to have multiple independently movable sets of concentrated photovoltaic solar (CPV) cells; and
locating the CPV cells in two or more paddle assemblies which couple to a common roll axle, where each of the multiple paddle assemblies contains its own set of the CPV solar cells that is independently movable on its own tilt axle from other sets of CPV cells on that two axis tracking mechanism, and where each paddle assembly has its own drive mechanism for that tilt axle.

14. The method for the two-axis tracker mechanism for the concentrated photovoltaic system of claim 13, further comprising:
maintaining a roll axis alignment of the solar tracking mechanism between neighboring independently moveable CPV paddle pairs with at least two or more roll bearing assemblies with pin holes, and where each roll bearing assembly couples and pins to the common roll axle between the stanchions.

15. The method for the two-axis tracker mechanism for the concentrated photovoltaic system of claim 13, further comprising:
driving each paddle pair assembly with its own tilt axis linear actuator to allow independent movement and optimization of that paddle pair with respect to other paddle pairs in the two-axis tracker mechanism, where each tilt-axle pivots perpendicular to the common roll axle.

16. The method for the two-axis tracker mechanism for the concentrated photovoltaic system of claim 15, further comprising:
coupling a first paddle assembly to a folding structure coupled to the first paddle assembly;
connecting the folding structure to one end of a first linear actuator, where the folding structure has multiple curved brackets each with hinges to fold flat against the first paddle assembly when the paddle assembly is shipped;
connecting a center truss between the multiple curved brackets when installed in the field to allow the connected linear actuator to cause paddle tilt articulation on the tilt axle; and
configuring each paddle assembly to rotate on its own tilt axis and the paddle assemblies to all rotate together in the roll axis on the common roll axle.

17. The two-axis tracker mechanism for the concentrated photovoltaic system of claim 13, further comprising;
coupling together via any of 1) a coupling mechanism, 2) a roll bearing assembly, 3) a slew drive motor coupling to a flanged narrower section of the conical shaped roll axle, and 4) any combination of the three, where the common roll axle includes two or more conical shaped sections of roll axles; and
where the multiple paddle-pairs each have a tilt-axle that pivots perpendicular to the common roll axle and a wider section of the conical shaped roll axle is connected approximate the tilt-axle.

18. The method for the two-axis tracker mechanism for the concentrated photovoltaic system of claim 13, further comprising:
sliding each paddle assembly with a centerline aligned tube onto its tilt axle, where two or more tilt axles couple to the common roll axle and each side of the tilt axle has a paddle assembly slid and secured onto that tilt axle.

19. The method for the two axis tracker mechanism for the concentrated photovoltaic system of claim 13, where a paddle assembly is constructed such that its set of CPV cells contained in the paddle assembly maintain their alignment in three dimensions when installed in the paddle assembly, where each paddle assembly has a skeleton frame that contains multiple individual CPV cells arranged in a grid like pattern that are pre-aligned in the three dimensions with each other during the fabrication process when the concentrated photovoltaic cells are installed in the paddle assembly, and this structure of the paddle assembly maintains the three dimensional alignment of the installed CPV cells during shipment as well as during an operation of the two axis tracker mechanism.

20. The method for the two-axis tracker mechanism for the concentrated photovoltaic system of claim 13, further comprising:
using a set of magnetic reed sensors, one at each measured axis, to determine 1) a reference position for the tilt linear actuators to control the tilt axis of the CPV cells as well as 2) a reference position for the slew drive motor to control the roll axis of the CPV cells;
locating the magnetic reed sensors to allow a degree of rotation on the roll axis of the solar tracker to be accurately correlatable to a number of rotations of the slew drive motor;
locating the magnetic reed sensors to allow a position along each linear actuator to be accurately correlatable to a degree of rotation on the tilt axis of the solar tracker.
